(19) United States
(12) Patent Application Publication
(10) Pub. No.: US 2026/0329032 A1
(43) Pub. Date: Oct. 22, 2026

(54) Semiconductor Device and Method of Making a Stackable Rigid-Flex Optics Module with Flex Cable Forming Channel

(71) Applicant: STATS ChipPAC Management Pte. Ltd., Singapore (SG)

(72) Inventor: Gai Leong Lai, Singapore (SG)

(73) Assignee: STATS ChipPAC Management Pte. Ltd., Singapore (SG)

(21) Appl. No.: 19/181,883

(22) Filed: Apr. 17, 2025

(51) Int. Cl. G02B 6/42

(52) U.S. Cl. CPC G02B 6/4248; G02B 6/4238; G02B 6/4239; G02B 6/428

(57) ABSTRACT

A semiconductor device has a first co-packaged optics (CPO) module and a second CPO module stacked over the first CPO module. The first CPO module has a first flex cable. A substrate is attached to the first flex cable. A first semiconductor die and a first photonic semiconductor die are disposed over the first flex cable opposite the substrate. The first flex cable is deformed to attach the first flex cable to a side surface of the first photonic semiconductor die. The second CPO module has a second flex cable. A second semiconductor die and a second photonic semiconductor die are disposed over a first portion of the second flex cable. A second portion of the second flex cable is folded over the second semiconductor die and second photonic semiconductor die.

### FIELD OF THE INVENTION

The present invention relates in general to semiconductor devices and, more particularly, to semiconductor devices and methods of making a stackable rigid-flex co-packaged optics (CPO) module with the flex cable forming a channel.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Photonic semiconductor devices, which are capable of transmitting or receiving signals via light, are becoming more and more common. Inter-device transmission via light has many advantages over electrical signals, particularly the avoidance of losses due to wire resistance and reduction of the impact of electromagnetic interference (EMI). However, the options for packaging photonic semiconductor devices have heretofore been limited and unsatisfactory in many ways. Therefore, a need exists for improved co-packaged optics (CPO) modules and methods of making them.

### BRIEF DESCRIPTION OF THE DRAWINGS

FIGS. 1a-1c illustrate a semiconductor wafer with a plurality of semiconductor die separated by a saw street;

FIGS. 2a-2i illustrate a process of forming a rigid-flex co-package optics module with the semiconductor die;

FIGS. 3a-3e illustrate a stackable co-package optics module;

FIGS. 4a-4c illustrate stacking the two co-packaged optics modules to form a stacked optical package;

FIG. 5 illustrates a flipped embodiment; and

FIGS. 6a and 6b illustrate an electronic device with the stacked optical package.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

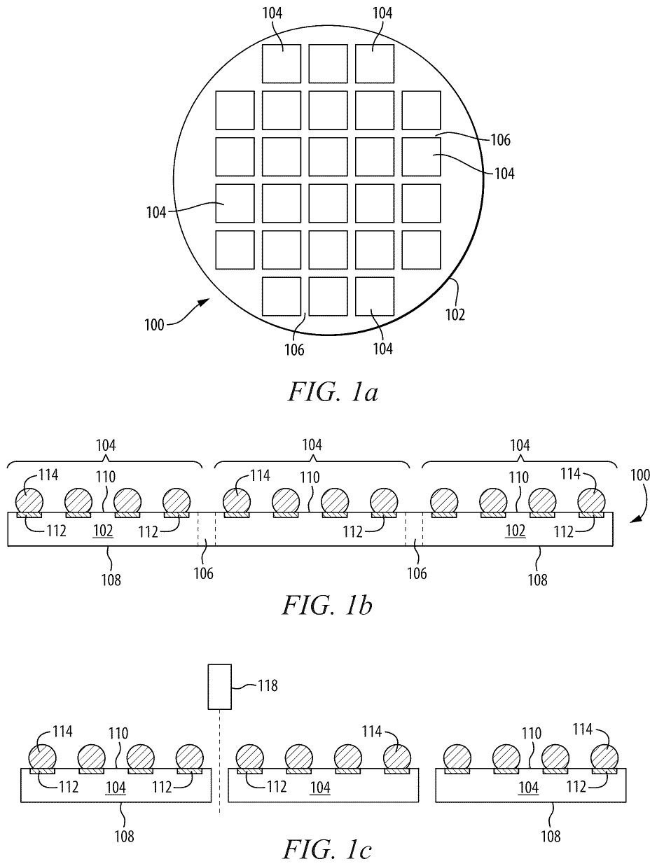

FIG. 1a shows a semiconductor wafer 100 with a base substrate material 102, such as silicon, germanium, aluminum phosphide, aluminum arsenide, gallium arsenide, gallium nitride, indium phosphide, silicon carbide, silicon nitride, lithium niobate (LiNbO3), or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under-bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

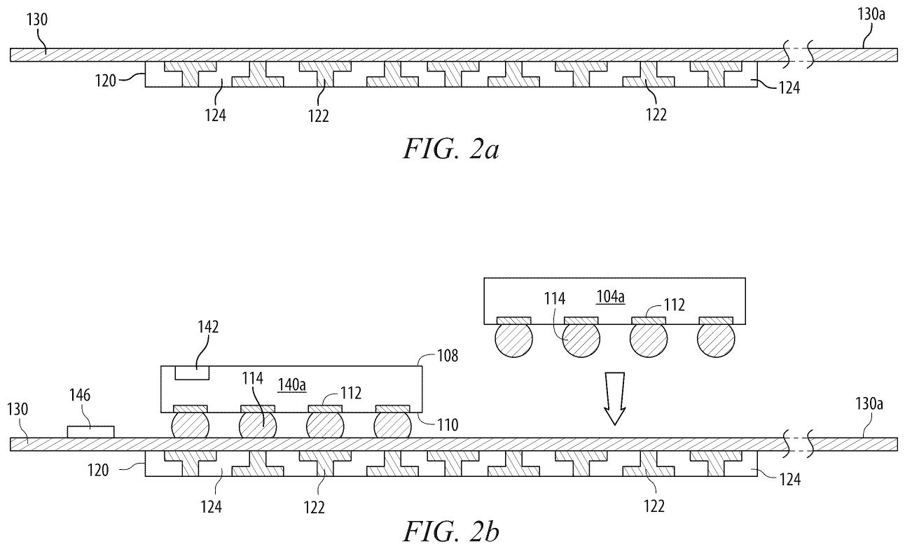

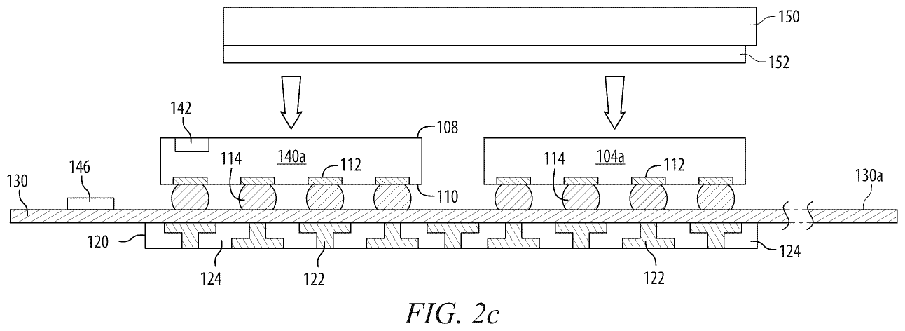

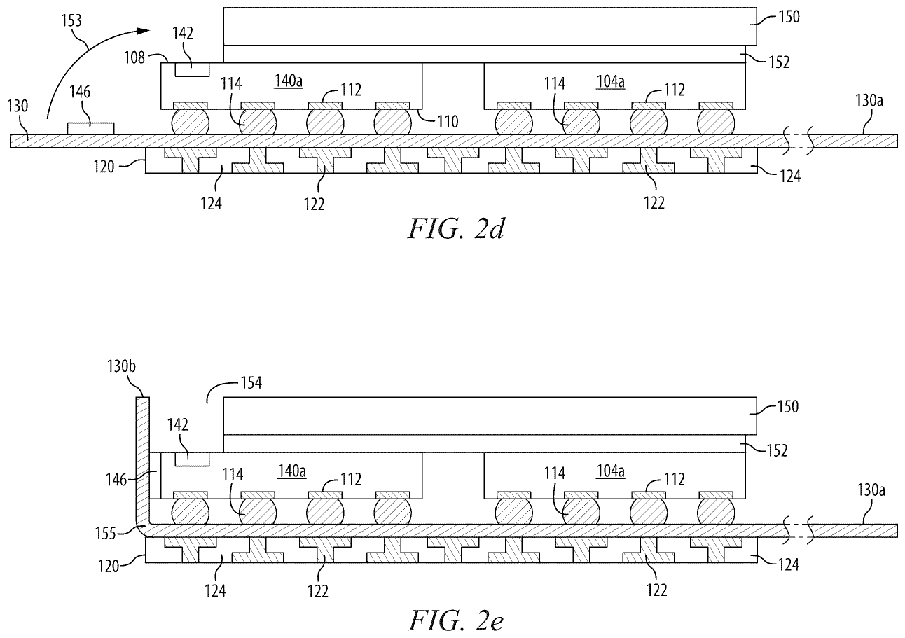

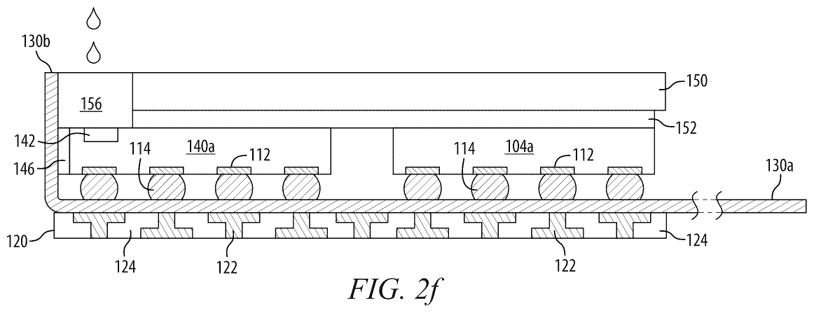

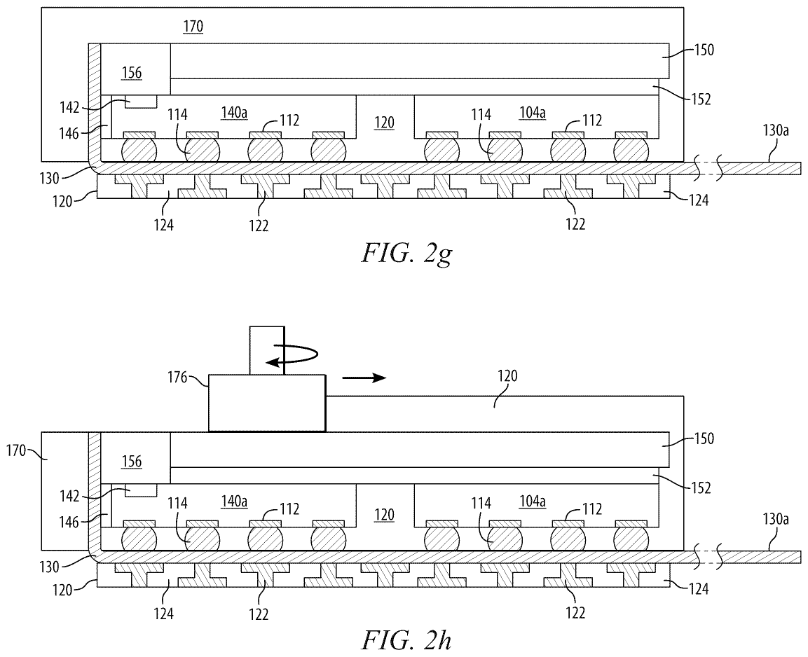

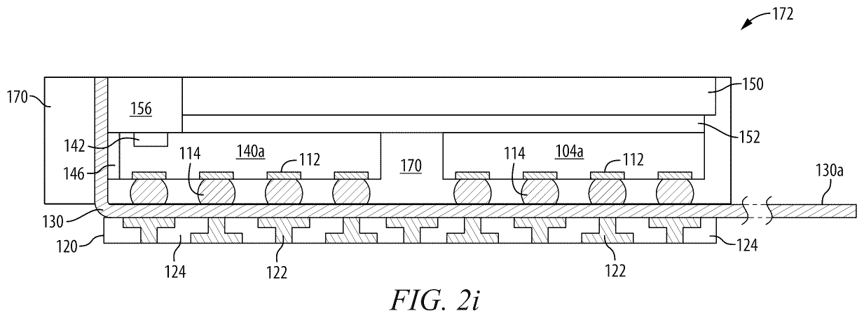

FIGS. 2a-2j illustrate the formation of a rigid-flex co-package optics module with semiconductor die 104. FIG. 2a shows a substrate 120. Substrate 120 is a multi-layered interconnect substrate including conductive layers 122 and insulating layers 124. Conductive layers 122 can be one or more layers of Al, Cu, Sn, Ni, Au, Ag, or other suitable electrically conductive material. Conductive layers 122 can be formed using PVD, CVD, electrolytic plating, electroless plating, or other suitable metal deposition process. Conductive layers 122 provide horizontal electrical interconnect across substrate 120 and vertical electrical interconnect between top and bottom surfaces. Portions of conductive layers 122 can be electrically common or electrically isolated depending on the design and function of the package or module being formed.

Insulating layers 124 contain one or more layers of SiO2, Si3N4, SiON, Ta2O5, Al2O3, solder resist, PI, BCB, PBO, and other material having similar insulating and structural properties. Insulating layers 124 can be formed using PVD, CVD, printing, lamination, spin coating, spray coating, sintering, thermal oxidation, or another suitable process. Insulating layers 124 provide isolation between conductive layers 122. Any number of conductive layers 122 and insulating layers 124 can be interleaved over each other to form substrate 120.

Any other suitable type of package substrate or leadframe is used for substrate 120 in other embodiments. For example, substrate 120 can be a laminate interposer, PCB, wafer-form, strip interposer, leadframe, or another suitable substrate. Substrate 120 may include one or more laminated layers of polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics.

Substrate 120 is formed on or attached to a flex cable 130. Flex cable 130 is a flexible cable with a plurality of conductive traces extending in parallel within an insulating film. Flex cable 130 can be any type of ribbon cable, flexible flat cable (FFC), or flexible printed circuit (FPC). The insulating film can be polyimide, polyester, or another suitable insulating material, such as those mentioned above for insulating layer 124. The internal conductors can be copper, steel, aluminum, gold, or another suitable conductive material.

Flex cable 130 is flexible, allowing the flex cable to bend and electrically connect to a connector that does not perfectly align to substrate 120. End 130a of flex cable 130 has exposed contacts that a connector will electrically connect to when the end of the flex cable is inserted into the connector. In other embodiments, a board-to-board or other type of connector is mounted onto end 130a for subsequent electrical interconnection. The conductive traces in flex cable 130 extend left-to-right in the figure to connect substrate 120 to end 130a.

The conductors of flex cable 130 can be screen printed onto an insulating film or patterned using photolithography. The patterned conductors can be laminated between two insulating films with a thermosetting adhesive coating that is activated by the laminating process. Any suitable process can be used to form flex cable 130 as a flexible cable with internal conductors. Flex cable 130 can be attached to substrate 120 by a conductive adhesive. In other embodiments, substrate 120 is formed directly on flex cable 130 by building up insulating layers 124 and conductive layers 122 directly onto the flex cable using thin film deposition techniques. Substrate 120 is considered to be attached to flex cable 130 even in embodiments where the substrate is formed directly on the flex cable. The CPO module being formed is referred to as a rigid-flex module because flex cable 130 is held rigid in the area where substrate 120 is attached and remains flexible elsewhere.

In FIG. 2b, a normal electronic semiconductor die 104a and photonic semiconductor die 140a are disposed over and mounted to flex cable 130. Semiconductor die 104a is a semiconductor die 104 from FIG. 1c, or another semiconductor die formed and functioning similarly. Photonic semiconductor die 140a is formed in a similar manner to semiconductor die 104 in FIGS. 1a-1c, with the addition of being manufactured with an optically sensitive or photonic region 142 on back surface 108. Photonic region 142 is formed of a material capable of, or otherwise configured to, convert external optical or light signals received at the photonic region to electrical signals within photonic semiconductor die 140a that can then be processed by circuits of active surface 110 or back surface 108.

In some embodiments, photonic semiconductor die 140a is a photonic integrated circuit (PIC) containing photonic components that form a functioning circuit capable of detecting, generating, transporting or processing light. Semiconductor die 140a can be formed of indium phosphide (InP), which allows for the integration of various optically active and passive functions on the same chip. Photonic region 142 is configured to receive an optical signal into the photonic circuits of semiconductor die 140a, either directly from the air or through an attached fiber-optic cable.

In some embodiments, photonic region 142 has a physical structure adapted to receive a fiber optic cable or signal, e.g., a grating coupler, and optionally has a separate connector mounted onto the surface of photonic semiconductor die 140a. In other embodiments, semiconductor die 140a is configured to emit light from photonic region 142. Semiconductor die 140a may have multiple photonic regions 142, e.g., one or more for receiving optical signals and one or more for transmitting optical signals.

Both semiconductor die 140a and 104a are picked and placed over flex cable 130 with solder bumps 114 oriented toward the flex cable. Solder bumps 114 are aligned to exposed contact pads of flex cable 130. Solder bumps 114 are reflowed to physically and electrically connect semiconductor die 140a and 104a to the conductive traces embedded in flex cable 130. An underfill is optionally used under semiconductor die 104a and 140a to physically support the solder connections. A portion of adhesive 146 is disposed on flex cable 130 adjacent to photonic semiconductor die 140a by, e.g., inkjet printing. A size and shape of adhesive 146 is configured to correspond to a side surface of photonic semiconductor die 140a when flex cable 130 is folded up in a later manufacturing stage.

In FIG. 2c, a heat spreader 150 is disposed over and placed down onto back surfaces 108 of semiconductor die 104a and 140a. Heat spreader 150 is a block of solid material, such as steel, aluminum, copper, alloys thereof, or another thermally conductive material. Heat spreader 150 can be cut to shape from a sheet of material. A thermal interface material (TIM) 152 is disposed on a surface of heat spreader 150 oriented toward semiconductor die 104a and 140a. TIM 152 can be any suitable type of thermal material, such as thermal paste, thermal adhesive, or a thermally conductive pad. A thermal adhesive can be used to adhere heat spreader 150 to semiconductor die 104a and 140a during subsequent manufacturing steps. Heat spreader 150 absorbs thermal energy generated by semiconductor die 104a and 140a and presents a smooth surface external to the package being formed. The external surface of heat spreader 150 can have a heatsink attached thereto if necessary to more efficiently dissipate the thermal energy to ambient air. TIM 152 improves thermal transfer between the semiconductor die and heat spreader 150.

In FIG. 2d, heat spreader 150 has been mounted onto the back surfaces 108 of semiconductor die 104a and 140a. Photonic region 142 remains exposed from heat spreader 150. Heat spreader 150 is a rectangle in some embodiments and placed outside a footprint of photonic region 142. In other embodiments, heat spreader 150 can have a concavity in plan view in which photonic region 142 is located so that the heat spreader extends to the left edge of photonic semiconductor die 140a in other cross-sections. In one embodiment, heat spreader 150 has an internal opening to accommodate photonic region 142.

Flex cable 130 is folded up as indicated by arrow 153, or otherwise deformed, such that adhesive 146 contacts a side surface of photonic semiconductor die 140a in FIG. 2e. The fold of flex cable 130 creates a rounded or radiused corner 155. The radius of corner 155 can be as large as necessary to allow flex cable 130 to fold without being damaged. In some embodiments, the internal conductors of flex cable 130 do not extend beyond the footprint of semiconductor die 140a to corner 155 so that the flex cable can be folded without bending the conductors. In that case, only the laminated insulating film needs to be bent, which allows a tighter radius of corner 155. Adhesive 146 holds flex cable 130 at a right angle across corner 155.

A length of flex cable 130 to the left of photonic semiconductor die 140a is selected such that the end 130b of the flex cable reaches approximately to the height of the top surface of heat spreader 150 after folding at corner 155. In other embodiments, end 130b of flex cable 130 can be cut after folding to be even with the top plane of heat spreader 150. The area between end 130b of flex cable 130 and heat spreader 150 creates a channel or recess 154 over photonic region 142. The folded portion of flex cable 130 operates as a sidewall for recess 154. Recess 154 can extend for an entire width of photonic semiconductor die 140a into and out of the page of FIG. 2e. In other embodiments, heat spreader 150 extends to the vertical portion of flex cable 130 in other cross sections, bounding recess 154 on three sides while the fourth side is bounded by the flex cable. Adhesive 146 optionally extends higher up to couple flex cable 130 to heat spreader 150 in embodiments where the heat spreader extends to the left edge of photonic semiconductor die 140a in other cross-sections.

In FIG. 2f, a temporary protection layer 156 is formed over photonic region 142. Protection layer 156 fills recess 154. Protection layer 156 can be deposited as a liquid as illustrated, inserted as a preformed plug, built up using thin film deposition techniques, or using any other suitable process. Protection layer 156 can be formed of a photoresist material, epoxy, or any of the methods and materials mentioned above or below for insulating layers or encapsulants. A top surface of protection layer 156 is made coplanar to end 130b of flex cable 130 and a top surface of heat spreader 150 by depositing material for the protection layer to that height or by backgrinding.

In FIG. 2g, an encapsulant or molding compound 170 is deposited over flex cable 130, substrate 120, and semiconductor die 104a and 140a. Encapsulant 170 is deposited using a paste printing, compression molding, transfer molding, liquid encapsulant molding, vacuum lamination, spin coating, or other suitable applicator. Encapsulant 170 can be liquid or granular polymer composite material, such as epoxy resin, epoxy acrylate, or another suitable polymer, with or without a filler. Encapsulant 170 is non-conductive, provides structural support, and environmentally protects the embedded electrical components from external elements and contaminants.

Encapsulant 170 is deposited in a mold with end 130a of flex cable 130 extending outside of the mold so that the encapsulant does not completely cover the flex cable. Encapsulant 170 fills in the space between flex cable 130, semiconductor die 104a and photonic semiconductor die 140a. Encapsulant 170 is backgrinded with a grinder 176 in FIG. 2h to complete a CPO module 172. FIG. 2i shows CPO module 172 after backgrinding. CPO module 172 has a normal electronic semiconductor die 104a co-packaged with an optical or photonic semiconductor die 140a. End 130a of flex cable 130 extends out from encapsulant 170 for subsequent electrical interconnect to an external system. CPO module 172 may be considered a chiplet.

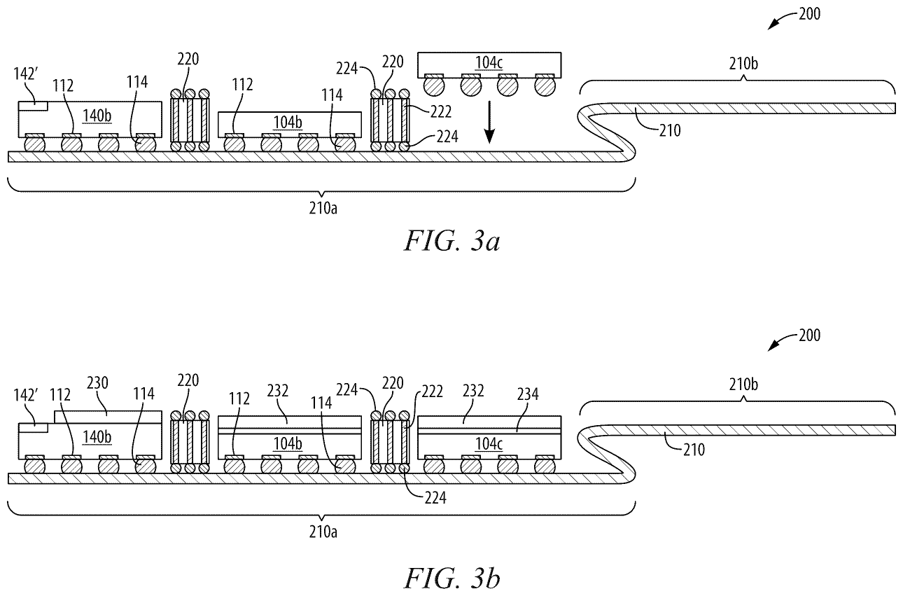

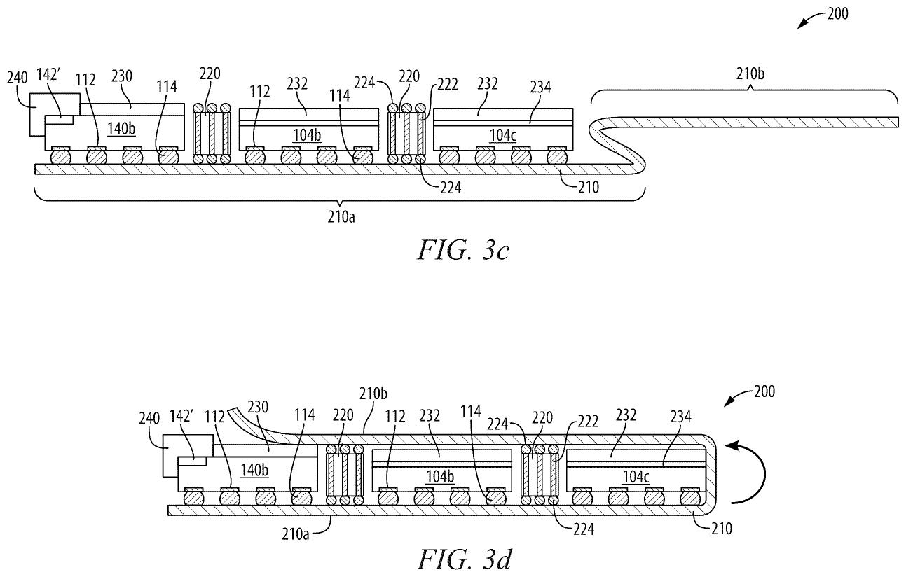

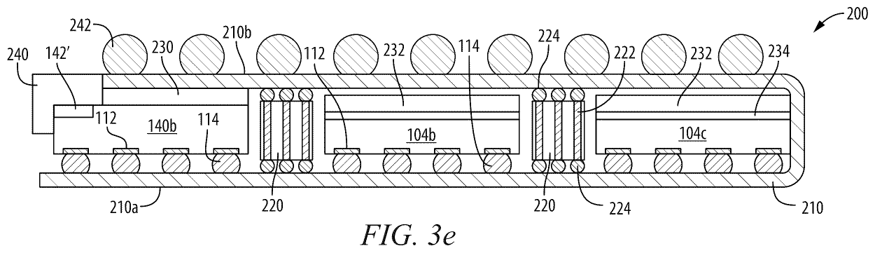

FIGS. 3a-3e illustrate a process of forming a stackable flex CPO module 200 for stacking on rigid-flex CPO module 172. CPO module 200 is formed on a flex cable 210 as illustrated in FIG. 3a. Flex cable 210 is structured and operates similarly to flex cable 130. In some embodiments, flex cable 210 is disposed on a rigid carrier for the manufacturing of CPO module 200. CPO module 200 is formed by disposing semiconductor die 104b, semiconductor die 104c, and photonic semiconductor die 140b on flex cable 210 as described above for semiconductor die 104a and 140a on flex cable 130. The semiconductor die are disposed on a first portion 210a of flex cable 210 while another portion 210b remains loose for later use.

In addition to semiconductor die 140b, 104b, and 104c, PCB units or e-bars 220 are disposed on flex cable 210 for vertical interconnect. PCB units 220 are formed of a base insulating material with conductive vias or pillars 222 formed through the insulating material. Solder bumps 224 are formed on each side of each conductive via 222 as described above for solder bumps 114. In some embodiments, a UBM is formed between each conductive vias 222 and each solder ball 224.

The base insulating material of PCB units 220 is typically composed of a dielectric substance such as FR-4 (a glass-reinforced epoxy laminate), polyimide, or ceramic, chosen based on the application's thermal, mechanical, and electrical requirements. Conductive vias 222 are typically made of copper, but any of the materials described above for conductive layers are used in other embodiments. Conductive vias 222 are formed by drilling holes through the base insulating material and then filling with conductive material using any of the methods described above for conductive layers generally. Additional layers, such as a solder mask, a silkscreen, or a conductive layer for signal redistribution or shielding, may be applied to the top and bottom surfaces.

PCB units 220 are picked and placed onto flex cable 210 as with semiconductor die 104 and 140. A separate PCB unit 220 is disposed between each die as illustrated. Each PCB unit 220 can extend into the page with a length that approximately matches a parallel dimension of the semiconductor die. Any configuration of PCB units 220 can be used in other embodiments, e.g., additional PCB units on the outer edges of the die, or surrounding each die with PCB units. Some pairs of adjacent die do not have a PCB unit therebetween in some embodiments.

Photonic semiconductor die 140b can have photonic region 142′ formed at an edge of the photonic semiconductor die as illustrated, in which case CPO module 200 will be appropriate for use with an edge fiber optic coupler. In other embodiments, photonic semiconductor die 140b uses the same photonic region 142 formed at an edge of the photonic semiconductor die, as was used above with photonic semiconductor die 140a, making a vertical fiber optic coupler more appropriate.

In FIG. 3b, a spacer or adhesive 230 is disposed on photonic semiconductor die 140b. Spacer 230 fills in a gap over photonic semiconductor die 140b that will exist when portion 210b of flex cable 210 is folded over onto the photonic semiconductor die. In one embodiment a top of spacer 230 is approximately even with tops of solder bumps 224. Heat spreaders 232 are mounted onto semiconductor die 104b and 104c with a TIM 234 as described above for heat spreader 150 and TIM 152. Heat spreaders 232 help with thermal management of semiconductor die 104b and 104c. TIM 234 is a thermal paste, adhesive, or sheet to attach heat spreaders 232 and efficiently transfer thermal energy from the die to the heat spreaders.

In FIG. 3c, a protection layer 240 is formed over photonic region 142′ of photonic semiconductor die 140b. Protection layer 240 is a conformal temporary protection layer, e.g., a sacrificial mask, photoresist layer, or epoxy localized to cover only over photonic region 142′. Protection layer 240 can be formed of any of the materials and using any of the methods mentioned above for insulating layers generally. Alternatively, protection layer 240 can be printed onto photonic region 142′ or be a preformed portion of adhesive tape disposed over the photonic region. Protection layer 240 protects photonic region 142′ during subsequent processing.

In FIG. 3d, portion 210b of flex cable 210 is folded over semiconductor die 104b, 104c, and 140b. The end of the flex cable for portion 210b, opposite portion 210a, falls short of photonic region 142′ so that flex cable 210 does not interfere with operation of the photonic region. Portion 210b rests on spacer 230 with an optional adhesive to stick flex cable 210 to the top of photonic semiconductor die 140b. Spacer 230 keeps flex cable 210 offset at an appropriate height for solder bumps 224 to be reflowed onto the flex cable. Bumps 224 are reflowed to physically and electrically couple the top bumps 224 of each PCB unit 220 to flex cable 210 portion 210b.

CPO module 200 is completed in FIG. 3e by adding solder bumps 242 onto flex cable 210 portion 210b. Bumps 242 allow electrical interconnect to semiconductor die 104b, 104c, and 140b through flex cable 210 and PCB units 220. PCB units 220 directly connect portions 210a and 210b of flex cable 210 without requiring a path through the folded side of the flex cable, thus creating a shorter electrical path to the semiconductor die than if all signals were transported only through flex cable 210. Moreover, more external electrical signals can be provided than would otherwise be possible if each had to be transmitted through a separate parallel trace through flex cable 210. CPO module 200 may be considered a chiplet.

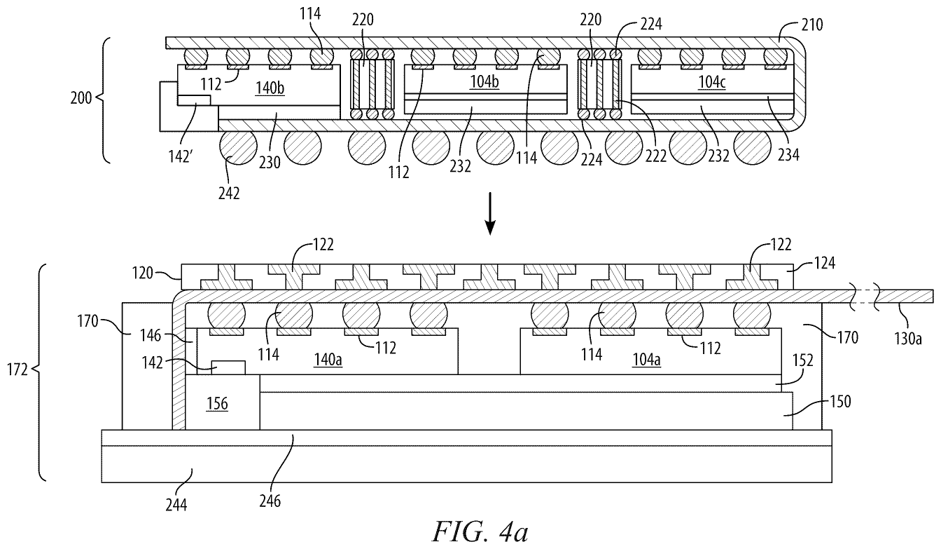

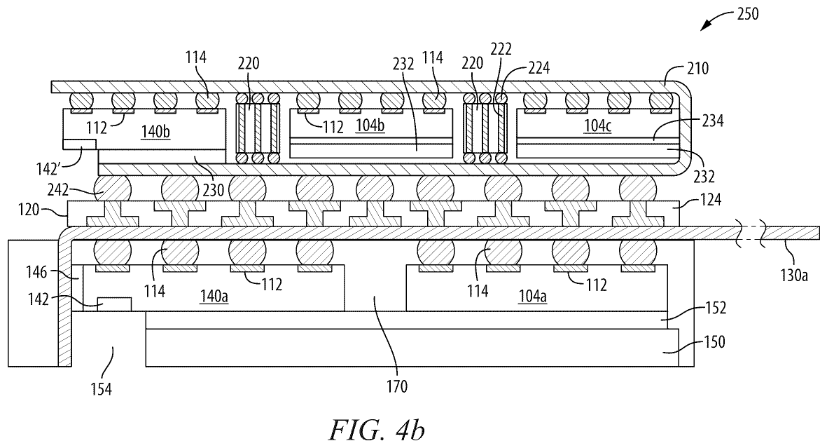

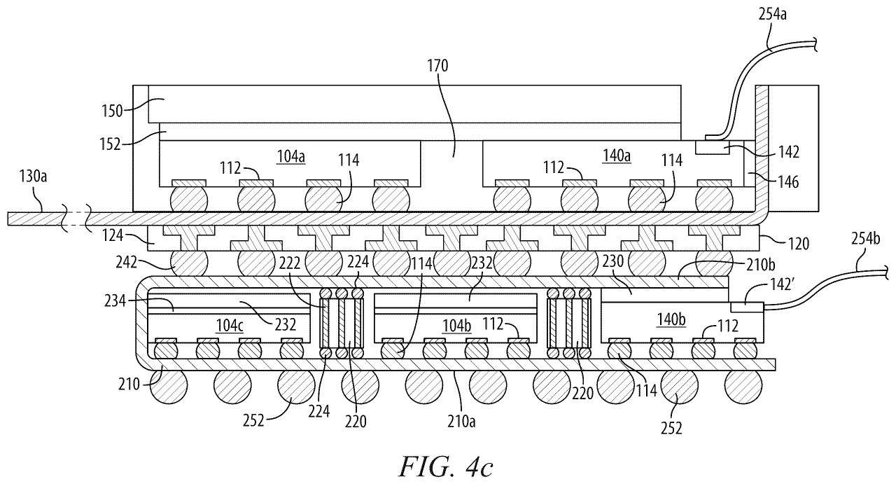

FIGS. 4a-4c illustrate forming a stacked package with CPO modules 172 and 200. The formation of the stack beings in FIG. 4 a with a carrier 244 or other suitable substrate. A releasable adhesive layer 246 is disposed over carrier 244. CPO module 172 is disposed on carrier 244 with heat spreader 150 on the carrier and substrate 120 oriented up away from the carrier. CPO module 200 is picked and placed over CPO module 172 with bumps 242 oriented down toward substrate 120. CPO module 200 is set on substrate 120, and bumps 242 are reflowed onto contact pads of conductive layer 122 to physically and electrically couple CPO modules 172 and 200 to each other. Semiconductor die 140a and 104a are electrically coupled to CPO module 200 through flex cable 130, substrate 120, and bumps 242.

FIG. 4b illustrates stacked CPO module 250. Carrier 244 is removed by a suitable mechanism, e.g., thermal release, UV release, or backgrinding. Protection layer 156 is removed by chemical etching, mechanical etching, physically pulling, laser ablation, or another suitable means to clear recess 154 and expose photonic region 142 of photonic semiconductor die 140a.

In FIG. 4c, bumps 252 are formed on flex cable 210 of bottom CPO module 200 as described above for bumps 114 and 242. In other embodiments, bumps 252 are formed at the same stage as bumps 242. Bumps 252 are used to mount and electrically connect stacked CPO module 250 to a PCB or substrate of a larger electrical device or system to incorporate the functionality of the stack.

Exemplary fiber optic cables 254 are illustrated in FIG. 4c. Fiber optic cables 254 are usually added after stack 250 is installed into the larger system but are shown with the stack in isolation for reference. Fiber optic cables 254 can be attached to photonic regions 142 using an adhesive, using a coupler previously mounted or formed over the photonic region, or using any other suitable means. Fiber optic cables 254 extend from a photonic region 142 to another device or coupler remote to stacked CPO module 250, which the stacked CPO module is able to communicate with via the fiber optic cable. In some embodiment fiber optic cables 254 include a fiber array unit (FAU). Fiber optic cable 254a is attached via a vertical coupler to photonic semiconductor die 140a. Fiber optic cable 254b is attached via an edge coupler to photonic semiconductor die 140b.

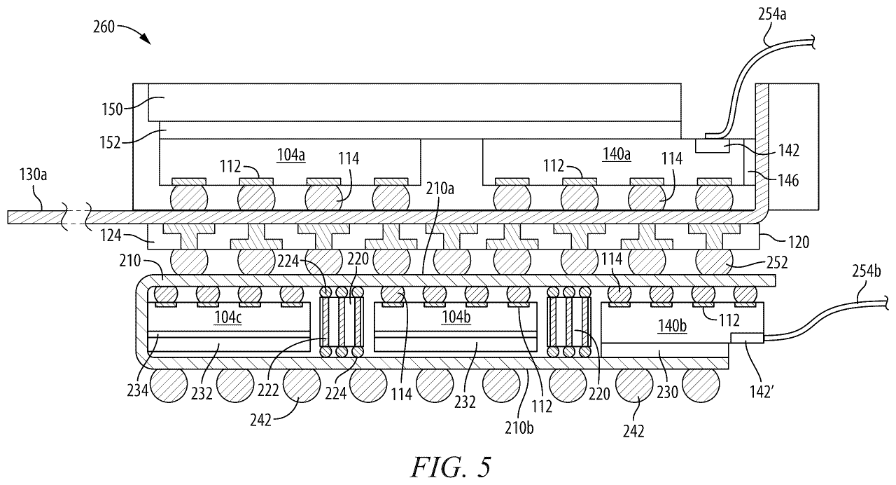

FIG. 5 illustrates an alternative embodiment as stacked CPO module 260 with the bottom CPO module 200 flipped vertically relative to stacked CPO module 250 of FIGS. 4a-4c. Solder bumps 252 are used to attach bottom CPO module 200 to CPO module 172 instead of bumps 242. Bumps 242 remain available for subsequent attachment of stack 260 to the substrate of a larger electrical system. In stack 260, photonic region 142′ of photonic semiconductor die 140b is oriented downward toward the substrate of the larger system, which may be more convenient for vertical fiber optic couplers. The longer portion 210a of flex cable 210 allows more I/O due to having a larger footprint size, which may be more desirable either for external or internal interconnect depending on the particular application.

Stacked CPO modules 250 and 260 are formed of two separate CPO modules 172 and 200. CPO module 172 is assembled on a rigid-flex substrate as a rigid-flex module. The flex extension part 130a of the rigid-flex substrate is deformed as a side wall to protect a vertical coupler or just photonic region 142 during processing. The flexible substrate provided by flex cable 210 of CPO module 200 presents as dual interposers with a longer and a shorter end, providing flexibility for signal routing. CPO module 200 can be formed with edge or vertical fiber optic connector options. Heat spreaders are applied to non-photonic semiconductor die 104 to assist in dissipating heat and enhance reliability and life span.

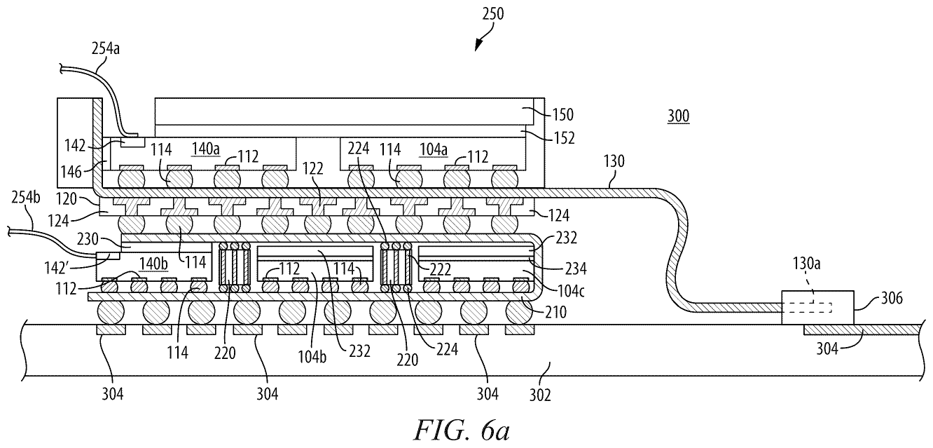

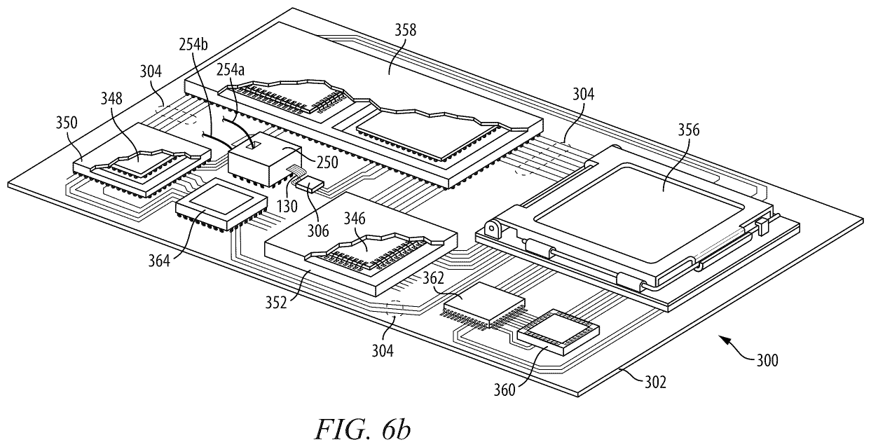

FIGS. 6a and 6b illustrate integrating the above-described semiconductor packages, e.g., stacked CPO module 250, into a larger electronic device 300. FIG. 6a illustrates a partial cross-section of stacked CPO module 250 mounted onto a printed circuit board (PCB) or other substrate 302 as part of electronic device 300. Bumps 252 are reflowed onto contact pads of conductive layer 304 to electrically and mechanically couple stacked CPO module 250 to substrate 302. Flex cable 130 is routed so that end 130a of the flex cable extends into a connector 306. Connector 306 is soldered onto conductive layer 304 of PCB 302 and has internal electrical contacts that apply pressure against exposed contacts of flex cable 130 for electrical connection. In some embodiment, connector 306 is disposed on a separate PCB or on another semiconductor package, rather than directly onto the same PCB 302 that stack 250 is mounted on and connected to with bumps 252.

Semiconductor die 104a, 104b, 104c, 140a, and 104b are electrically coupled to conductive layer 304 through substrate 120, flex cable 130, and connector 306 in parallel with flex cable 210 and bumps 252. Optical fibers 254a and 254b are attached to photonic regions 142 to provide optical functionality to device 300. Photonic semiconductor die 140a and 140b are used by electronic device 300 to send or receive an optical signal via the optical fibers or perform any other suitable optical function.

FIG. 6b illustrates electronic device 300 having a chip carrier substrate or PCB 302 with a plurality of semiconductor packages disposed on a surface of PCB 302, including stacked CPO module 250. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 6b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

The reference numbers 104, 104a, 104b, and 104c refer to semiconductor die with purely electronic functionality. The reference numbers 140, 140a, and 140b refer to semiconductor die with photonic functionality or capability. While three normal semiconductor die 104 and two photonic semiconductor die 140 are shown in the illustrated embodiments, any number and combination of die can be used, including more than one photonic semiconductor die in a single package or module. Any other desired electrical components, such as additional die, subpackages, chiplets, or discrete active or passive devices, can be installed on flex cable 130 or 210 as desired along with the semiconductor die. The term semiconductor die can refer to either an optical semiconductor die or a normal electrical-function-only semiconductor die.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
forming a first co-packaged optics (CPO) module by,
providing a first flex cable,
attaching a substrate to the first flex cable,
disposing a first semiconductor die and a first photonic semiconductor die over the first flex cable opposite the substrate, and
deforming the first flex cable to attach the first flex cable to a side surface of the first photonic semiconductor die;
forming a second CPO module by,
providing a second flex cable,
disposing a second semiconductor die and a second photonic semiconductor die over a first portion of the second flex cable, and
folding a second portion of the second flex cable over the second semiconductor die and second photonic semiconductor die to dispose the second semiconductor die and second photonic semiconductor die between the first portion and second portion of the second flex cable; and
stacking the second CPO module over the first CPO module.

2. The method of claim 1, further including disposing a solder bump between the first CPO module and second CPO module.

3. The method of claim 1, further including disposing a PCB unit between the second semiconductor die and second photonic semiconductor die.

4. The method of claim 1, further including connecting a first fiber optic cable to the first photonic semiconductor die and a second fiber optic cable to the second photonic semiconductor die.

5. The method of claim 1, further including depositing an encapsulant over the first flex cable, substrate, first semiconductor die, and first photonic semiconductor die.

6. The method of claim 1, further including disposing a heat spreader over the first semiconductor die or second semiconductor die.

7. A method of making a semiconductor device, comprising:
forming a first co-packaged optics (CPO) module by,
providing a first flex cable,
attaching a substrate to the first flex cable,
disposing a first photonic semiconductor die over the first flex cable opposite the substrate, and
deforming the first flex cable to attach the first flex cable to a side surface of the first photonic semiconductor die;
forming a second CPO module by,
providing a second flex cable,
disposing a second photonic semiconductor die over a first portion of the second flex cable, and
folding a second portion of the second flex cable over the second photonic semiconductor die; and
stacking the second CPO module over the first CPO module.

8. The method of claim 7, further including disposing a solder bump between the first CPO module and second CPO module over a first side of the second CPO module.

9. The method of claim 8, further including disposing a second solder bump over a second side of the second CPO module opposite the first side.

10. The method of claim 7, further including disposing a PCB unit on the second flex cable.

11. The method of claim 7, further including connecting a first fiber optic cable to the first photonic semiconductor die and a second fiber optic cable to the second photonic semiconductor die.

12. The method of claim 7, further including depositing an encapsulant over the first flex cable, substrate, and first photonic semiconductor die.

13. The method of claim 7, further including depositing a protective material into a recess formed by the deformation of the first flex cable.

14. A semiconductor device, comprising:
a first co-packaged optics (CPO) module including,
a first flex cable,
a substrate attached to the first flex cable, and
a first semiconductor die and a first photonic semiconductor die disposed over the first flex cable opposite the substrate,
wherein the first flex cable is deformed such that the first flex cable is attached to a side surface of the first photonic semiconductor die; and
a second CPO module stacked over the first CPO module, wherein the second CPO module includes,
a second flex cable, and
a second semiconductor die and a second photonic semiconductor die disposed over a first portion of the second flex cable,
wherein a second portion of the second flex cable is folded over the second semiconductor die and second photonic semiconductor die such that the second semiconductor die and second photonic semiconductor die are disposed between the first portion and second portion of the second flex cable.

15. The semiconductor device of claim 14, further including a solder bump disposed between the first CPO module and second CPO module.

16. The semiconductor device of claim 14, further including a PCB unit disposed between the second semiconductor die and second photonic semiconductor die.

17. The semiconductor device of claim 14, further including:
a first fiber optic cable coupled to the first photonic semiconductor die; and
a second fiber optic cable coupled to the second photonic semiconductor die.

18. The semiconductor device of claim 14, further including an encapsulant deposited over the first flex cable, substrate, first semiconductor die, and first photonic semiconductor die.

19. The semiconductor device of claim 14, further including a heat spreader disposed over the first semiconductor die or second semiconductor die.

20. A semiconductor device, comprising:
a first co-packaged optics (CPO) module including,
a first flex cable,
a substrate attached to the first flex cable, and
a first photonic semiconductor die disposed over the first flex cable opposite the substrate,
wherein the first flex cable is deformed such that the first flex cable is attached to a side surface of the first photonic semiconductor die; and
a second CPO module stacked over the first CPO module, wherein the second CPO module includes,
a second flex cable, and
a second photonic semiconductor die disposed over a first portion of the second flex cable,
wherein a second portion of the second flex cable is folded over the second photonic semiconductor die.

21. The semiconductor device of claim 20, further including a solder bump disposed between the first CPO module and second CPO module over a first side of the second CPO module.

22. The semiconductor device of claim 21, further including a second solder bump disposed over a second side of the second CPO module opposite the first side.

23. The semiconductor device of claim 20, further including a PCB unit disposed on the second flex cable.

24. The semiconductor device of claim 20, further including:
a first fiber optic cable coupled to the first photonic semiconductor die; and
a second fiber optic cable coupled to the second photonic semiconductor die.

25. The semiconductor device of claim 20, further including an encapsulant deposited over the first flex cable, substrate, and first photonic semiconductor die.
